(19) United States
(12) Patent Application Publication
(10) Pub. No.: US 2020/0152713 A1
(43) Pub. Date: May 14, 2020

(54) DISPLAY PANEL AND ORGANIC LIGHT EMITTING DISPLAY DEVICE INCLUDING THE SAME

(71) Applicant: Samsung Display Co., Ltd., Yongin-Si (KR)

(72) Inventors: Sanghoon YIM, Suwon-si (KR); Donghoon KIM, Suwon-si (KR); Youngseo PARK, Yongin-si (KR); Jinsook BANG, Hwaseong-si (KR)

(21) Appl. No.: 16/599,591

(22) Filed: Oct. 11, 2019

(30) Foreign Application Priority Data
Nov. 12, 2018 (KR) 10-2018-0137892

(51) Int. Cl. H01L 27/32; H01L 51/52

(52) U.S. Cl. CPC H01L 27/3218; H01L 51/5206

(57) ABSTRACT

A display panel includes first pixels each including a first organic light emitting element which outputs red color light, second pixels each including a second organic light emitting element which outputs green color light, and third pixels each including a third organic light emitting element which outputs blue color light. The first organic light emitting elements are arranged in point symmetry with respect to the second organic light emitting element, the third organic light emitting elements are arranged in point symmetry with respect to the second organic light emitting element, an anode of the first organic light emitting element is spaced apart from an anode of the second organic light emitting element by a first distance, and the anode of the second organic light emitting element is spaced apart from an anode of the third organic light emitting element by a second distance which is shorter than the first distance.

### CROSS-REFERENCE TO RELATED APPLICATION(S)

This application claims priority to Korean Patent Application No. 10-2018-0137892, filed on Nov. 12, 2018, and all the benefits accruing therefrom under 35 U.S.C. § 119, the content of which in its entirety is herein incorporated by reference.

### BACKGROUND

### 1. Technical Field

Exemplary embodiments relate to a display device. More particularly, exemplary embodiments of the inventive concept relate to a display panel including a plurality of pixels each including an organic light emitting element (e.g., an organic light emitting diode) and an organic light emitting display device including the display panel.

### 2. Description of the Related Art

Generally, a display panel of an organic light emitting display device may include first pixels each including a first organic light emitting element that outputs a red color light, second pixels each including a second organic light emitting element that outputs a green color light, and third pixels each including a third organic light emitting element that outputs a blue color light.

### SUMMARY

Because material-characteristics of the first through third organic light emitting elements are different from each other, driving voltages applied to the first through third pixels to implement the same grayscale may be also different. For example, when the first through third pixels implement the same grayscale, the driving voltage applied to the second pixel may be higher than the driving voltage applied to the first pixel, and the driving voltage applied to the third pixel may be higher than the driving voltage applied to the second pixel. Thus, a lateral leakage current may flow between adjacent pixels due to differences of the driving voltages applied to the first through third pixels. For example, since the driving voltages applied to the first through third pixels are relatively low when a low-grayscale is implemented, resistances of the first through third organic light emitting elements included therein may be relatively high, and thus an effect of relatively reducing lateral resistances (or lateral resistors) existing between adjacent pixels may occur. As a result, the lateral leakage current may flow through the lateral resistances existing between adjacent pixels. In other words, the lateral leakage current may flow from the third pixel that outputs the blue color light into the second pixel that outputs the green color light, and the lateral leakage current may flow from the second pixel that outputs the green color light into the first pixel that outputs the red color light. Here, a light emission of the first pixel that outputs the red color light may be greatly affected by the lateral leakage current while a light emission of the second pixel that outputs the green color light is not greatly affected by the lateral leakage current. As a result, when a low-grayscale is implemented, the first pixel that outputs the red color light may be over-emitted by the lateral leakage current, and thus a low-grayscale color shift phenomenon in which an image becomes reddish may occur.

Some exemplary embodiments provide a display panel including first through third pixels that are arranged to prevent (or reduce) a low-grayscale color shift phenomenon in which an image becomes reddish when a low-grayscale is implemented, where each pixel includes an organic light emitting element.

Some exemplary embodiments provide an organic light emitting display device including the display panel above.

According to exemplary embodiments, a display panel includes a plurality of first pixels, where each of the plurality of first pixels includes a first organic light emitting element which outputs a red color light, a plurality of second pixels, where each of the plurality of second pixels includes a second organic light emitting element which outputs a green color light, and a plurality of third pixels, where each of the plurality of first pixels includes a third organic light emitting element which outputs a blue color light. Here, the first organic light emitting elements are arranged in point symmetry with respect to the second organic light emitting element, the third organic light emitting elements are arranged in point symmetry with respect to the second organic light emitting element, an anode of the first organic light emitting element is spaced apart from an anode of the second organic light emitting element by a first distance, the anode of the second organic light emitting element is spaced apart from an anode of the third organic light emitting element by a second distance, and the first distance is longer than the second distance.

In exemplary embodiments, the anode of the third organic light emitting element may be spaced apart from the anode of the first organic light emitting element by a third distance, and the third distance is longer than the first distance.

In exemplary embodiments, one side of the anode of the second organic light emitting element may be parallel with at least one side of the anode of the first organic light emitting element, and another side of the anode of the second organic light emitting element may be parallel with at least one side of the anode of the third organic light emitting element.

In exemplary embodiments, the anode of the second organic light emitting element may have an octagonal shape, and each of the anode of the first organic light emitting element and the anode of the third organic light emitting element may have a polygonal shape.

In exemplary embodiments, a major axis of the anode of the second organic light emitting element may extend in a direction toward the anode of the third organic light emitting element, and a minor axis of the anode of the second organic light emitting element may extend in a direction toward the anode of the first organic light emitting element.

In exemplary embodiments, an area of the anode of the first organic light emitting element may be different from an area of the anode of the third organic light emitting element.

In exemplary embodiments, the area of the anode of the first organic light emitting element may be smaller than the area of the anode of the third organic light emitting element.

In exemplary embodiments, an area of the anode of the second organic light emitting element may be smaller than the area of the anode of the first organic light emitting element.

In exemplary embodiments, an area of the anode of the first organic light emitting element may be equal to an area of the anode of the third organic light emitting element.

In exemplary embodiments, an area of the anode of the second organic light emitting element may be smaller than the area of the anode of the first organic light emitting element and the area of the anode of the third organic light emitting element.

According to exemplary embodiments, an organic light emitting display device includes a display panel which includes a plurality of first pixels each including a first organic light emitting element which outputs a red color light, a plurality of second pixels each including a second organic light emitting element which outputs a green color light, and a plurality of third pixels each including a third organic light emitting element which outputs a blue color light, and a display panel driving circuit which drives the display panel. Here, the display panel has a pixel arrangement structure in which the first organic light emitting elements are arranged in point symmetry with respect to the second organic light emitting element, the third organic light emitting elements are arranged in point symmetry with respect to the second organic light emitting element, an anode of the first organic light emitting element is spaced apart from an anode of the second organic light emitting element by a first distance, the anode of the second organic light emitting element is spaced apart from an anode of the third organic light emitting element by a second distance, and the first distance is longer than the second distance.

In exemplary embodiments, the anode of the third organic light emitting element may be spaced apart from the anode of the first organic light emitting element by a third distance, and the third distance is longer than the first distance.

In exemplary embodiments, one side of the anode of the second organic light emitting element may be parallel with at least one side of the anode of the first organic light emitting element, and another side of the anode of the second organic light emitting element may be parallel with at least one side of the anode of the third organic light emitting element.

In exemplary embodiments, the anode of the second organic light emitting element may have an octagonal shape, and each of the anode of the first organic light emitting element and the anode of the third organic light emitting element may have a polygonal shape.

In exemplary embodiments, a major axis of the anode of the second organic light emitting element may extend in a direction toward the anode of the third organic light emitting element, and a minor axis of the anode of the second organic light emitting element may extend in a direction toward the anode of the first organic light emitting element.

In exemplary embodiments, an area of the anode of the first organic light emitting element may be different from an area of the anode of the third organic light emitting element.

In exemplary embodiments, the area of the anode of the first organic light emitting element may be smaller than the area of the anode of the third organic light emitting element.

In exemplary embodiments, an area of the anode of the second organic light emitting element may be smaller than the area of the anode of the first organic light emitting element.

In exemplary embodiments, an area of the anode of the first organic light emitting element may be equal to an area of the anode of the third organic light emitting element.

In exemplary embodiments, an area of the anode of the second organic light emitting element may be smaller than the area of the anode of the first organic light emitting element and the area of the anode of the third organic light emitting element.

Therefore, a display panel according to exemplary embodiments may include first pixels each including a first organic light emitting element that outputs a red color light, second pixels each including a second organic light emitting element that outputs a green color light, and third pixels each including a third organic light emitting element that outputs a blue color light. Here, the display panel has a pixel arrangement structure in which the first organic light emitting elements are arranged (or placed) in point symmetry with respect to the second organic light emitting element, the third organic light emitting elements are arranged in point symmetry with respect to the second organic light emitting element, an anode of the first organic light emitting element is spaced apart from an anode of the second organic light emitting element by a first distance, and the anode of the second organic light emitting element is spaced apart from an anode of the third organic light emitting element by a second distance, where the first distance is longer than the second distance. Thus, the display panel may reduce a lateral leakage current flowing from the second pixel that outputs the green color light into the first pixel that outputs the red color light by relatively increasing a lateral resistance existing between the second pixel that outputs the green color light and the first pixel that outputs the red color light. As a result, as compared to a conventional display panel, the display panel may prevent (or reduce) a low-grayscale color shift phenomenon in which an image becomes reddish when a low-grayscale is implemented.

In addition, an organic light emitting display device including the display panel according to exemplary embodiments may provide a high-quality image to a viewer (or user).

### BRIEF DESCRIPTION OF THE DRAWINGS

Illustrative, non-limiting exemplary embodiments will be more clearly understood from the following detailed description in conjunction with the accompanying drawings.

FIG. 1 is a diagram illustrating an exemplary embodiment of a display panel according to the invention.

FIG. 2 is a diagram illustrating an example in which first through third pixels are arranged in the display panel of FIG. 1.

FIG. 3 is a diagram illustrating an example in which first through third pixels are arranged in a conventional display panel.

FIGS. 4 and 5 are diagrams for describing that a lateral leakage current occurs between a first pixel and a second pixel in a conventional display panel.

FIG. 6 is a diagram for describing that a low-grayscale color shift phenomenon is prevented (or reduced) in the display panel of FIG. 1.

FIG. 7 is a block diagram illustrating an exemplary embodiment of an organic light emitting display device according to the invention.

FIG. 8 is a block diagram illustrating an exemplary embodiment of an electronic device according to the invention.

FIG. 9 is a diagram illustrating an example in which the electronic device of FIG. 8 is implemented as a smart phone.

### DETAILED DESCRIPTION

Hereinafter, embodiments of the inventive concept will be explained in detail with reference to the accompanying drawings.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

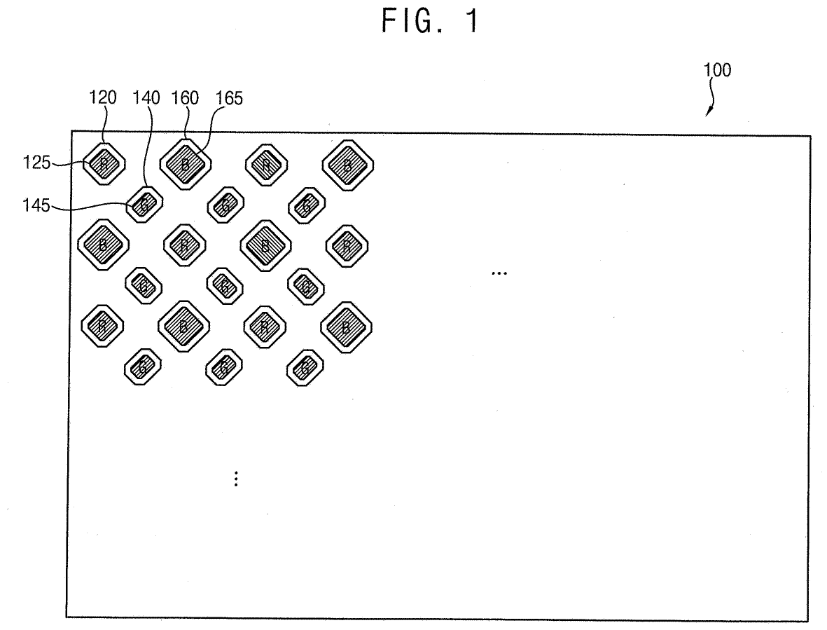

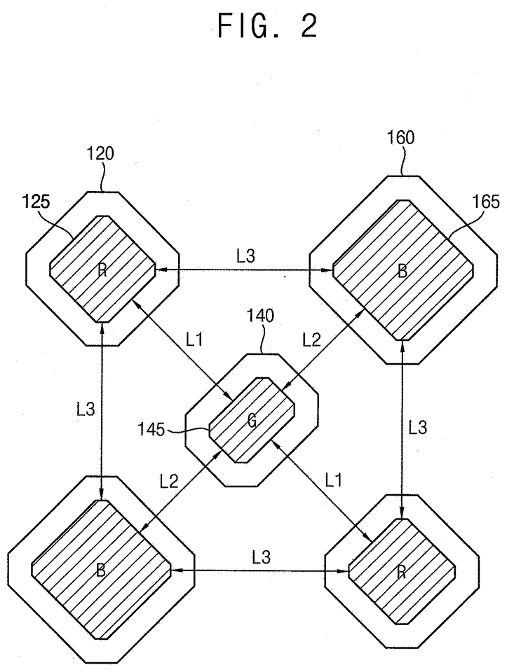

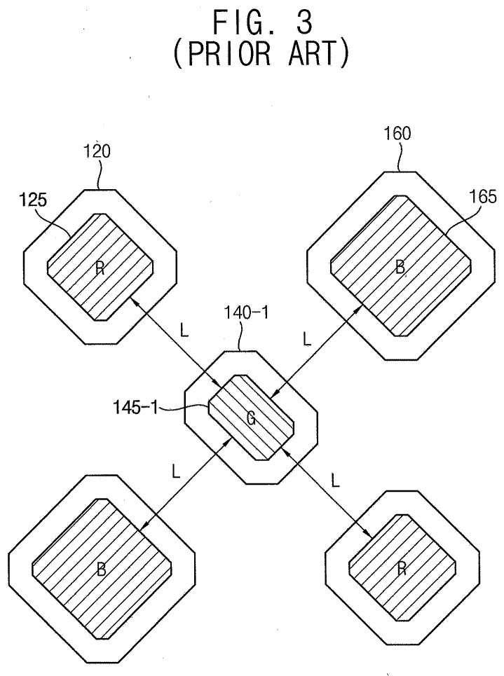

FIG. 1 is a diagram illustrating an exemplary embodiment of a display panel according to the invention, FIG. 2 is a diagram illustrating an example in which first through third pixels are arranged in the display panel of FIG. 1, and FIG. 3 is a diagram illustrating an example in which first through third pixels are arranged in a conventional display panel.

Referring to FIGS. 1 to 3, the display panel 100 may include first pixels 120 each including a first organic light emitting element (e.g., an organic light emitting diode) that outputs a red color light, second pixels 140 each including a second organic light emitting element that outputs a green color light, and third pixels 160 each including a third organic light emitting element that outputs a blue color light. The display panel 100 may display an image based on the red color light output from the first pixels 120, the green color light output from the second pixels 140, and the blue color light output from the third pixels 160.

In the display panel 100, the first pixels 120 each including the first organic light emitting element that outputs the red color light, the second pixels 140 each including the second organic light emitting element that outputs the green color light, and the third pixels 160 each including the third organic light emitting element that outputs the blue color light may be arranged adjacent to each other. Here, the first pixels 120 are arranged (or disposed) in point symmetry with respect to the second pixel 140, and the third pixels 160 are arranged in point symmetry with respect to the second pixel 140. That is, the first organic light emitting elements of the first pixels 120 are arranged in point symmetry with respect to the second organic light emitting element of the second pixel 140, and the third organic light emitting elements of the third pixels 160 are arranged in point symmetry with respect to the second organic light emitting element of the second pixel 140. For example, two first pixels 120 and two third pixels 160 may be arranged to surround one second pixel 140, two first pixels 120 may face each other with one second pixel 140 as a center between them, and two third pixels 160 may face each other with one second pixel 140 as a center between them. In an exemplary embodiment, an anode 145 of the second organic light emitting element of the second pixel 140 may have an octagonal shape, an anode 125 of the first organic light emitting element of the first pixel 120 may have a polygonal shape (e.g., a tetragonal shape, a hexagon shape, an octagonal shape, etc.), and an anode 165 of the third organic light emitting element of the third pixel 160 may have a polygonal shape. Because material-characteristic of the first organic light emitting element of the first pixel 120, material-characteristic of the second organic light emitting element of the second pixel 140, and material-characteristic of the third organic light emitting element of the third pixel 160 are different from each other, a driving voltage applied to the first pixel 120, a driving voltage applied to the second pixel 140, and a driving voltage applied to the third pixel 160 to implement the same grayscale may be also different. For example, when the first through third pixels 120, 140, and 160 implement the same grayscale, the driving voltage applied to the third pixel 160 that outputs the blue color light may be the highest, and the driving voltage applied to the first pixel 120 that outputs the red color light may be the lowest.

For this reason, a lateral leakage current may flow from the third pixel 160 that outputs the blue color light into the second pixel 140 that outputs the green color light or into the first pixel 120 that outputs the red color light, and a lateral leakage current may flow from the second pixel 140 that outputs the green color light into the first pixel 120 that outputs the red color light. Here, the lateral leakage current may affect an image when especially a low-grayscale is implemented (i.e., when the driving voltages applied to the first through third pixels 120, 140, and 160 are relatively low) more than when a high-grayscale is implemented (i.e., when the driving voltages applied to the first through third pixels 120, 140, and 160 are relatively high). Generally, the lateral leakage current flowing from the third pixel 160 into the second pixel 140 may not generate a big problem because a light emission of the second pixel 140 that outputs the green color light is not greatly affected by the lateral leakage current. On the other hand, the lateral leakage current flowing from the second pixel 140 into the first pixel 120 may generate a big problem because a light emission of the first pixel 120 that outputs the red color light is greatly affected by the lateral leakage current (i.e., since a light emission efficiency of the first pixel 120 that outputs the red color light may be relatively high). Thus, when a low-grayscale is implemented, the first pixel 120 may be over-emitted by the lateral leakage current flowing from the second pixel 140 into the first pixel 120, and thus a low-grayscale color shift phenomenon in which an image becomes reddish may occur. Although the lateral leakage current also flows from the third pixel 160 into the first pixel 120, the lateral leakage current flowing from the second pixel 140 into the first pixel 120 rather than the lateral leakage current flowing from the third pixel 160 into the first pixel 120 generates a bigger problem because a distance (i.e., third distance L3) between the third pixel 160 and the first pixel 120 is longer than a distance (i.e., first distance L1) between the second pixel 140 and the first pixel 120. As used herein, the term “distance” between two pixels or between two anodes refers to the distance between the closest sides of the anodes of the two pixels. In addition, although the first pixel 120 is over-emitted by the lateral leakage current flowing from the second pixel 140 into the first pixel 120 when a high-grayscale is implemented, a color shift phenomenon is more conspicuous when the low-grayscale is implemented than when the high-grayscale is implemented because an amount of the additional light emission of the first pixel 120 due to the lateral leakage current is negligible as compared to an amount of a total light emission of the first pixel 120 when the high-grayscale is implemented.

In some exemplary embodiments, one side of the anode 145 of the second organic light emitting element of the second pixel 140 may be parallel with at least one side of the anode 125 of the first organic light emitting element of the first pixel 120, and another side of the anode 145 of the second organic light emitting element of the second pixel 140 may be parallel with at least one side of the anode 165 of the third organic light emitting element of the third pixel 160. In an exemplary embodiment, an area of the anode 125 of the first organic light emitting element of the first pixel 120 may be different from an area of the anode 165 of the third organic light emitting element of the third pixel 160. For example, as illustrated in FIG. 2, the area of the anode 125 of the first organic light emitting element of the first pixel 120 may be smaller than the area of the anode 165 of the third organic light emitting element of the third pixel 160. Here, an area of the anode 145 of the second organic light emitting element of the second pixel 140 may be smaller than the area of the anode 125 of the first organic light emitting element of the first pixel 120 and the area of the anode 165 of the third organic light emitting element of the third pixel 160. In another exemplary embodiment, the area of the anode 125 of the first organic light emitting element of the first pixel 120 may be equal to the area of the anode 165 of the third organic light emitting element of the third pixel 160. Here, the area of the anode 145 of the second organic light emitting element of the second pixel 140 may be smaller than the area of the anode 125 of the first organic light emitting element of the first pixel 120 and the area of the anode 165 of the third organic light emitting element of the third pixel 160. As illustrated in FIG. 2, the anode 125 of the first organic light emitting element of the first pixel 120 may be spaced apart from the anode 145 of the second organic light emitting element of the second pixel 140 by a first distance L1, the anode 145 of the second organic light emitting element of the second pixel 140 may be spaced apart from the anode 165 of the third organic light emitting element of the third pixel 160 by a second distance L2, and the anode 165 of the third organic light emitting element of the third pixel 160 may be spaced apart from the anode 125 of the first organic light emitting element of the first pixel 120 by a third distance L3. Here, the first distance L1 is longer than the second distance L2, and the third distance L3 is longer than the first distance L1 and the second distance L2. To this end, a major axis (i.e., longitudinal axis) of the anode 145 of the second organic light emitting element of the second pixel 140 may extend in a direction (i.e., L2 direction in FIG. 2) toward the anode 165 of the third organic light emitting element of the third pixel 160, and a minor axis (i.e., latitudinal axis) of the anode 145 of the second organic light emitting element of the second pixel 140 may extend in a direction (i.e., L1 direction in FIG. 2) toward the anode 125 of the first organic light emitting element of the first pixel 120.

On the other hand, in a conventional display panel as shown in FIG. 3, a distance L between the anode 125 of the first organic light emitting element of the first pixel 120 and the anode 145-1 of the second organic light emitting element of the second pixel 140-1 is equal to the distance L between the anode 165 of the third organic light emitting element of the third pixel 160 and the anode 145-1 of the second organic light emitting element of the second pixel 140-1. That is, the first distance L1 between the anode 125 of the first organic light emitting element of the first pixel 120 and the anode 145 of the second organic light emitting element of the second pixel 140 in the display panel 100 of the exemplary embodiment according to the invention may be relatively longer than the distance L between the anode 165 of the third organic light emitting element of the third pixel 160 and the anode 145-1 of the second organic light emitting element of the second pixel 140-1 in the conventional display panel if the other conditions are the same. Here, a major axis (i.e., longitudinal axis) of the anode 145-1 of the second organic light emitting element of the second pixel 140-1 may extend in a direction from the anode 145-1 toward the anode 125 of the first organic light emitting element of the first pixel 120, and a minor axis (i.e., latitudinal axis) of the anode 145-1 of the second organic light emitting element of the second pixel 140-1 may extend in a direction from the anode 145-1 toward the anode 165 of the third organic light emitting element of the third pixel 160. Thus, if the other conditions of the display panel 100 are the same as those of the conventional display panel, the lateral resistance existing between the first pixel 120 and the second pixel 140 in the exemplary embodiment according to the invention may be relatively higher than the lateral resistance existing between the first pixel 120 and the second pixel 140-1 in the conventional display panel, and thus the first lateral leakage current flowing from the second pixel 140 into the first pixel 120 may be relatively reduced in the display panel 100 compared with the conventional display panel. As a result, as compared to the conventional display panel, an amount of the additional light emission of the first pixel 120 due to the first lateral leakage current flowing from the second pixel 140 into the first pixel 120 especially when a low-grayscale is implemented, may be reduced, and thus the low-grayscale color-shift phenomenon in which an image becomes reddish may be prevented (or reduced) in the display panel 100. On the other hand, if the other conditions of the display panel 100 are the same as those of the conventional display panel, the second distance L2 between the anode 165 of the third organic light emitting element of the third pixel 160 and the anode 145 of the second organic light emitting element of the second pixel 140 may be relatively shorter in the display panel 100 according to the invention rather than the distance L between the anode 165 of the third organic light emitting element of the third pixel 160 and the anode 145-1 of the second organic light emitting element of the second pixel 140-1 in the conventional display panel. Hence, the second lateral resistance existing between the third pixel 160 and the second pixel 140 may be relatively low, and thus the first lateral leakage current flowing from the third pixel 160 into the second pixel 140 may be relatively increased in the display panel 100, compared with the conventional display panel. However, as described above, because the light emission of the second pixel 140 that outputs the green color light is not greatly affected by the lateral leakage current, an amount of the additional light emission of the second pixel 140 due to the second lateral leakage current flowing from the third pixel 160 into the second pixel 140 may be negligible.

In brief, the display panel 100 according to the exemplary embodiments includes the first pixels 120 each including the first organic light emitting element that outputs the red color light, the second pixels 140 each including the second organic light emitting element that outputs the green color light, and the third pixels 160 each including the third organic light emitting element that outputs the blue color light. Here, the display panel 100 has a pixel arrangement structure in which the first organic light emitting elements of the first pixels 120 are arranged in point symmetry with respect to the second organic light emitting element of the second pixel 140, the third organic light emitting elements of the third pixels 160 are arranged in point symmetry with respect to the second organic light emitting element of the second pixel 140, the anode 125 of the first organic light emitting element of the first pixel 120 is spaced apart from the anode 145 of the second organic light emitting element of the second pixel 140 by the first distance L1, and the anode 145 of the second organic light emitting element of the second pixel 140 is spaced apart from the anode 165 of the third organic light emitting element of the third pixel 160 by the second distance L2, where the first distance L1 is longer than the second distance L2. Thus, the display panel 100 may reduce the first lateral leakage current flowing from the second pixel 140 that outputs the green color light into the first pixel 120 that outputs the red color light by relatively increasing the first lateral resistance existing between the second pixel 140 that outputs the green color light and the first pixel 120 that outputs the red color light. As a result, as compared to the conventional display panel, the display panel 100 may prevent (or reduce) the low-grayscale color-shift phenomenon in which an image becomes reddish when a low-grayscale is implemented. Therefore, an organic light emitting display device including the display panel 100 may provide a high-quality image to a viewer (or user).

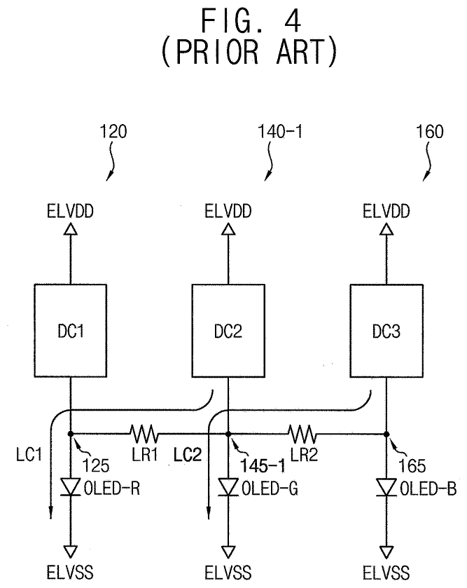

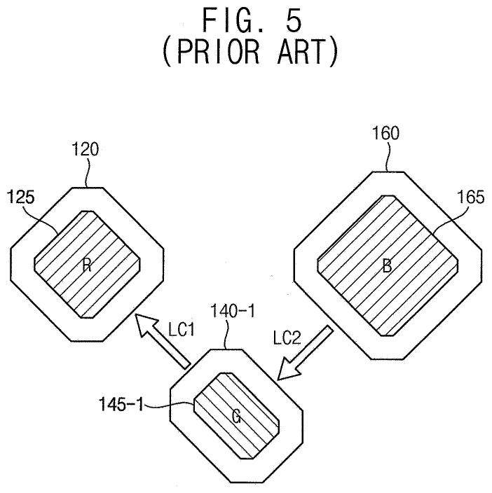

FIGS. 4 and 5 are diagrams for describing that a lateral leakage current occurs between a first pixel and a second pixel in a conventional display panel, and FIG. 6 is a diagram for describing that a low-grayscale color shift phenomenon is prevented (or reduced) in the display panel of FIG. 1. The internal structures of the pixels shown in FIG. 4 can also be applied to the display panel 100 according to the invention.

Referring to FIGS. 4 to 6, the first pixel 120 may include a first organic light emitting element driving circuit DC1 and a first organic light emitting element OLED-R, the second pixel 140-1 may include a second organic light emitting element driving circuit DC2 and a second organic light emitting element OLED-G, and the third pixel 160 may include a third organic light emitting element driving circuit DC3 and a third organic light emitting element OLED-B. A first power voltage ELVDD and a second power voltage ELVSS supplies the power to the first to third pixels 120 to 160. Here, the first organic light emitting element driving circuit DC1, the second organic light emitting element driving circuit DC2, and the third organic light emitting element driving circuit DC3 may have the same structure. For example, each of the first through third organic light emitting element driving circuits DC1, DC2, and DC3 may include a switching transistor, a driving transistor, a storage capacitor, etc.

As illustrated in FIGS. 4 and 5, in the conventional display panel, the first pixel 120 that outputs the red color light, the second pixel 140-1 that outputs the green color light, and the third pixel 160 that outputs the blue color light may be arranged adjacent to each other. Here, the first organic light emitting element driving circuit DC1 may control the first organic light emitting element OLED-R to emit the red color light, the second organic light emitting element driving circuit DC2 may control the second organic light emitting element OLED-G to emit the green color light, and the third organic light emitting element driving circuit DC3 may control the third organic light emitting element OLED-B to emit the blue color light. Specifically, the first organic light emitting element OLED-R may output the red color light in response to a driving current supplied from the first organic light emitting element driving circuit DC1 in the first pixel 120, the second organic light emitting element OLED-G may output the green color light in response to a driving current supplied from the second organic light emitting element driving circuit DC2 in the second pixel 140-1, and the third organic light emitting element OLED-B may output the blue color light in response to a driving current supplied from the third organic light emitting element driving circuit DC3 in the third pixel 160. As described above, since the first through third pixels 120, 140-1, and 160 are adjacent to each other, first and second lateral resistances LR1 and LR2 may exist among the first through third pixels 120, 140-1, and 160. That is, the first lateral resistance LR1 is a resistance between the first pixel 120 and the second pixel 140-1, and the second lateral resistance LR2 is a resistance between the second pixel 140-1 and the third pixel 160. In addition, the driving voltages applied to the first through third pixels 120, 140-1, and 160 to implement the same grayscale may be different from each other. Here, when the first through third pixels 120, 140-1, and 160 implement the same grayscale, the driving voltage applied to the third pixel 160 that outputs the blue color light may be the highest, the driving voltage applied to the second pixel 140-1 that outputs the green color light may be medium, and the driving voltage applied to the first pixel 120 that outputs the red color light may be the lowest. Thus, as illustrated in FIGS. 4 and 5, a second lateral leakage current LC2 may flow from the third pixel 160 into the second pixel 140-1 through the second lateral resistance LR2 because a voltage of the anode 165 of the third organic light emitting element OLED-B of the third pixel 160 is higher than a voltage of the anode 145-1 of the second organic light emitting element OLED-G of the second pixel 140-1. In addition, a first lateral leakage current LC1 may flow from the second pixel 140-1 into the first pixel 120 through the first lateral resistance LR1 because the voltage of the anode 145-1 of the second organic light emitting element OLED-G of the second pixel 140-1 is higher than a voltage of the anode 125 of the first organic light emitting element OLED-R of the first pixel 120.

As described above, the second lateral leakage current LC2 may flow from the third pixel 160 that outputs the blue color light into the second pixel 140-1 that outputs the green color light, and the first lateral leakage current LC1 may flow from the second pixel 140-1 that outputs the green color light into the first pixel 120 that outputs the red color light. However, the second lateral leakage current LC2 flowing from the third pixel 160 into the second pixel 140-1 may not generate a big problem because a light emission of the second pixel 140-1 that outputs the green color light is not greatly affected by the second lateral leakage current LC2. On the other hand, the first lateral leakage current LC1 flowing from the second pixel 140-1 into the first pixel 120 may generate a big problem because a light emission of the first pixel 120 that outputs the red color light is greatly affected by the first lateral leakage current LC1. For example, as illustrated in FIG. 6, when a low-grayscale is implemented, the first pixel 120 that outputs the red color light may be over-emitted by the first lateral leakage current LC1 flowing from the second pixel 140-1 into the first pixel 120, and thus a low-grayscale color-shift phenomenon in which an image becomes reddish may occur (i.e., indicated by a first color shift DI′ on color coordinates). To prevent (or reduce) the low-grayscale color-shift phenomenon, the display panel 100 according to the invention may have a pixel arrangement structure in which the first distance L1 between the anode 125 of the first organic light emitting element OLED-R of the first pixel 120 and the anode 145 of the second organic light emitting element OLED-G of the second pixel 140 is longer than the second distance L2 between the anode 145 of the second organic light emitting element OLED-G of the second pixel 140 and the anode 165 of the third organic light emitting element OLED-B of the third pixel 160. Thus, the display panel 100 may reduce the first lateral leakage current LC1 flowing from the second pixel 140 that outputs the green color light into the first pixel 120 that outputs the red color light by increasing the first lateral resistance LR1 existing between the first pixel 120 that outputs the red color light and the second pixel 140 that outputs the green color light. Here, although the second lateral resistance LR2 existing between the third pixel 160 and the second pixel 140 is decreased (i.e., the second lateral leakage current LC2 flowing from the third pixel 160 into the second pixel 140 is increased), as described above, an influence of the second lateral leakage current LC2 on the second pixel 140 may be negligible. As a result, the low-grayscale color-shift phenomenon in which an image becomes reddish may be reduced (i.e., indicated by a second color shift DI2 on color coordinates).

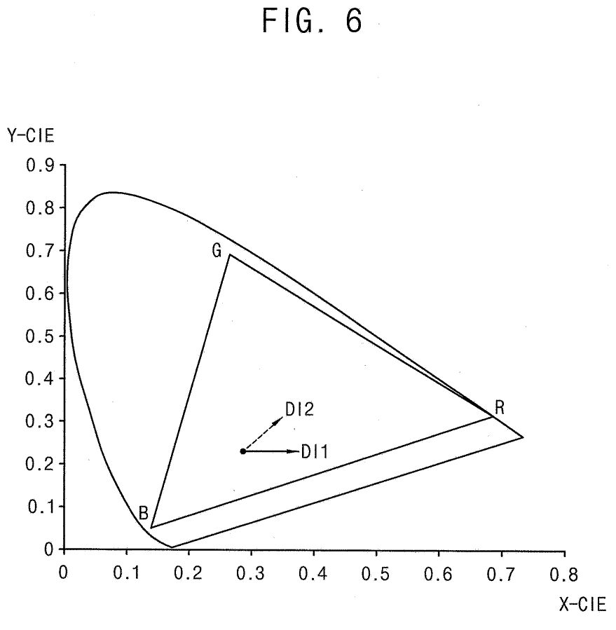

FIG. 7 is a block diagram illustrating an exemplary embodiment of an organic light emitting display device according to the invention.

Referring to FIG. 7, the organic light emitting display device 500 may include a display panel 510 and a display panel driving circuit 520.

The display panel 510 may include a plurality of pixels. Here, the pixels may include a plurality of first pixels each including a first organic light emitting element that outputs a red color light, a plurality of second pixels each including a second organic light emitting element that outputs a green color light, and a plurality of third pixels each including a third organic light emitting element that outputs a blue color light. Specifically, in the display panel 510, the first organic light emitting elements of the first pixels are arranged in point symmetry with respect to the second organic light emitting element of the second pixel, the third organic light emitting elements of the third pixels are arranged in point symmetry with respect to the second organic light emitting element of the second pixel, an anode of the first organic light emitting element of the first pixel may be spaced apart from an anode of the second organic light emitting element of the second pixel by a first distance, the anode of the second organic light emitting element of the second pixel may be spaced apart from an anode of the third organic light emitting element of the third pixel by a second distance, the anode of the third organic light emitting element of the third pixel may be spaced apart from the anode of the first organic light emitting element of the first pixel by a third distance, the first distance is longer than the second distance, and the third distance may be longer than the first distance and the second distance. Here, one side of the anode of the second organic light emitting element of the second pixel may be parallel with at least one side of the anode of the first organic light emitting element of the first pixel, and another side of the anode of the second organic light emitting element of the second pixel may be parallel with at least one side of the anode of the third organic light emitting element of the third pixel.

In some exemplary embodiments, the anode of the second organic light emitting element of the second pixel may have an octagonal shape, and each of the anode of the first organic light emitting element of the first pixel and the anode of the third organic light emitting element of the third pixel may have a polygonal shape. Here, a major axis (i.e., longitudinal axis) of the anode of the second organic light emitting element of the second pixel may extend in a direction toward the anode of the third organic light emitting element of the third pixel, and a minor axis (i.e., latitudinal axis) of the anode of the second organic light emitting element of the second pixel may extend in a direction toward the anode of the first organic light emitting element of the first pixel. Thus, the first distance by which the anode of the first organic light emitting element of the first pixel is spaced apart from the anode of the second organic light emitting element of the second pixel is longer than the second distance by which the anode of the third organic light emitting element of the third pixel is spaced apart from the anode of the second organic light emitting element of the second pixel. Hence, the first lateral resistance existing between the first pixel that outputs the red color light and the second pixel that outputs the green color light may be higher (or greater) than the second lateral resistance existing between the second pixel that outputs the green color light and the third pixel that outputs the blue color light. That is, as compared to a conventional display panel, the first lateral resistance existing between the first pixel that outputs the red color light and the second pixel that outputs the green color light is relatively high, and thus a first lateral leakage current flowing from the second pixel that outputs the green color light into the first pixel that outputs the red color light when a low-grayscale is implemented may be reduced in the display panel 510. As a result, as compared to the conventional display panel, a low-grayscale color shift phenomenon in which an image becomes reddish may be prevented (or reduced) in the display panel 510 according to the invention because an amount of additional light emission of the first pixel, which outputs the red color light, due to the first lateral leakage current flowing from the second pixel into the first pixel when a low-grayscale is implemented, is reduced in the display panel 510. Therefore, the organic light emitting display device 500 may provide a high-quality image to a viewer.

In an exemplary embodiment, an area of the anode of the first organic light emitting element of the first pixel may be different from an area of the anode of the third organic light emitting element of the third pixel. For example, the area of the anode of the first organic light emitting element of the first pixel may be smaller than the area of the anode of the third organic light emitting element of the third pixel. Here, the area of the anode of the second organic light emitting element of the second pixel may be smaller than the area of the anode of the first organic light emitting element of the first pixel. In another exemplary embodiment, the area of the anode of the first organic light emitting element of the first pixel may be equal to the area of the anode of the third organic light emitting element of the third pixel. Here, the area of the anode of the second organic light emitting element of the second pixel may be smaller than the area of the anode of the first organic light emitting element of the first pixel and the area of the anode of the third organic light emitting element of the third pixel. Since these are described above with reference to FIGS. 1 to 3, duplicated description related thereto will not be repeated. In exemplary embodiments, the display panel driving circuit 520 may drive the display panel 510. For this operation, the display panel driving circuit 520 may include a scan driver, a data driver, a timing controller, etc. In some exemplary embodiments, the display panel driving circuit 520 may further include an emission control driver. The display panel 510 may be connected to the data driver via a plurality of data-lines. The display panel 510 may be connected to the scan driver via a plurality of scan-lines. The display panel 510 may be connected to the emission control driver via a plurality of emission control-lines. Specifically, the data driver may provide a data signal DS to the display panel 510 via the data-lines, the scan driver may provide a scan signal SS to the display panel 510 via the scan-lines, and the emission control driver may provide an emission control signal ES to the display panel 510 via the emission control-lines. The timing controller may control the scan driver, the data driver, the emission control driver, etc.

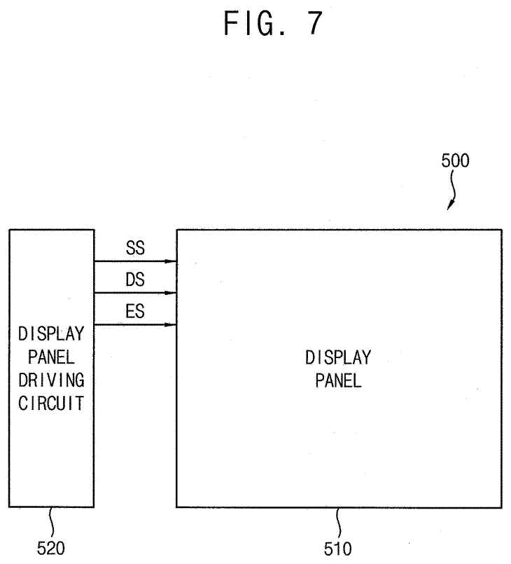

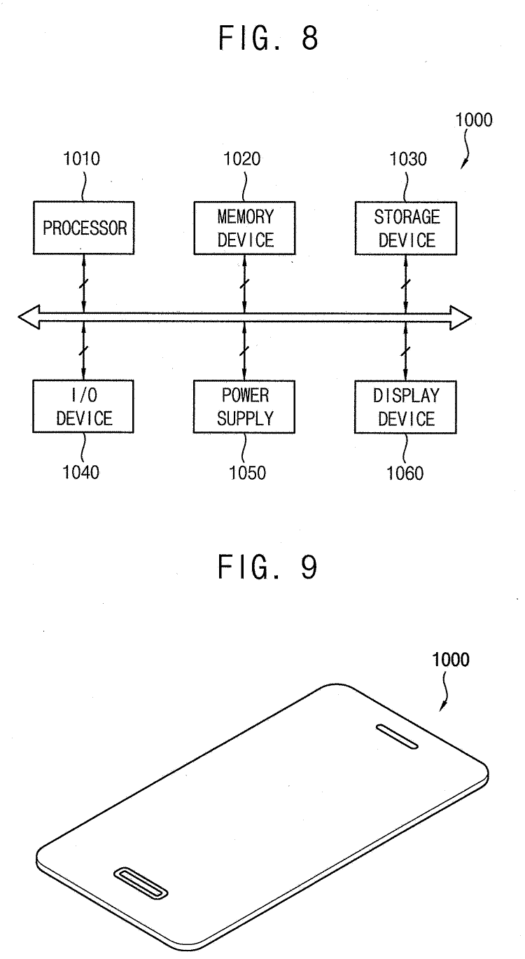

FIG. 8 is a block diagram illustrating an exemplary embodiment of an electronic device according to the invention, and FIG. 9 is a diagram illustrating an example in which the electronic device of FIG. 8 is implemented as a smart phone.

Referring to FIGS. 8 and 9, the electronic device 1000 may include a processor 1010, a memory device 1020, a storage device 1030, an input/output (I/O) device 1040, a power supply 1050, and an organic light emitting display device 1060. Here, the organic light emitting display device 1060 may be the same with the organic light emitting display device 500 of FIG. 7. In addition, the electronic device 1000 may further include a plurality of ports for communicating with a video card, a sound card, a memory card, a universal serial bus (“USB”) device, other electronic devices, etc. In an exemplary embodiment, as illustrated in FIG. 9, the electronic device 1000 may be implemented as a smart phone. However, the electronic device 1000 according to the invention is not limited thereto. For example, the electronic device 1000 may be implemented as a cellular phone, a video phone, a smart pad, a smart watch, a tablet PC, a car navigation system, a computer monitor, a laptop, a head mounted display (“MID”) device, etc.

The processor 1010 may perform various computing functions. The processor 1010 may be a microprocessor, a central processing unit (“CPU”), an application processor (“AP”), etc. The processor 1010 may be coupled to other components via an address bus, a control bus, a data bus, etc. Further, the processor 1010 may be coupled to an extended bus such as a peripheral component interconnection (“PCI”) bus. The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM)” device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, etc and/or at least one volatile memory device such as a dynamic random access memory (“DRAM”) device, a static random access memory (“SRAM”) device, a mobile DRAM device, etc. The storage device 1030 may include a solid state drive (“SSD”) device, a hard disk drive (“HDD”) device, a CD-ROM device, etc. The I/O device 1040 may include an input device such as a keyboard, a keypad, a mouse device, a touch-pad, a touch-screen, etc, and an output device such as a printer, a speaker, etc. The power supply 1050 may provide power for operations of the electronic device 1000.

The organic light emitting display device 1060 may be coupled to other components via the buses or other communication links. In some exemplary embodiments, the organic light emitting display device 1060 may be included in the I/O device 1040. As described above, the organic light emitting display device 1060 may include a display panel that can prevent (or reduce) a low-grayscale color shift phenomenon in which an image becomes reddish when a low-grayscale is implemented and a display panel driving circuit that drives the display panel. For this operation, the display panel may include first pixels each including a first organic light emitting element that outputs a red color light, second pixels each including a second organic light emitting element that outputs a green color light, and third pixels each including a third organic light emitting element that outputs a blue color light. Here, the display panel are a pixel arrangement structure in which the first organic light emitting elements are arranged in point symmetry with respect to the second organic light emitting element, the third organic light emitting elements are arranged in point symmetry with respect to the second organic light emitting element, an anode of the first organic light emitting element is spaced apart from an anode of the second organic light emitting element by a first distance, and the anode of the second organic light emitting element is spaced apart from an anode of the third organic light emitting element by a second distance, where the first distance is longer than the second distance. Thus, the display panel may reduce a lateral leakage current flowing from the second pixel that outputs the green color light into the first pixel that outputs the red color light by relatively increasing a lateral resistance existing between the second pixel that outputs the green color light and the first pixel that outputs the red color light. As a result, the display panel may prevent (or reduce) the low-grayscale color shift phenomenon, and the organic light emitting display device 1060 including the display panel may provide a high-quality image to a viewer. Since these are described above, duplicated description related thereto will not be repeated.

The inventive concept may be applied to an organic light emitting display device and an electronic device including the organic light emitting display device. For example, the inventive concept may be applied to a cellular phone, a smart phone, a video phone, a smart pad, a smart watch, a tablet PC, a car navigation system, a television, a computer monitor, a laptop, a head mounted display (HMD) device, an MP3 player, etc.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the inventive concept. Accordingly, all such modifications are intended to be included within the scope of the inventive concept as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A display panel comprising:
a plurality of first pixels, wherein each of the plurality of first pixels includes a first organic light emitting element which outputs a red color light;
a plurality of second pixels, wherein each of the plurality of second pixels includes a second organic light emitting element which outputs a green color light; and
a plurality of third pixels, wherein each of the plurality of third pixels includes a third organic light emitting element which outputs a blue color light,
wherein the first organic light emitting elements are arranged in point symmetry with respect to the second organic light emitting element, the third organic light emitting elements are arranged in point symmetry with respect to the second organic light emitting element, an anode of the first organic light emitting element is spaced apart from an anode of the second organic light emitting element by a first distance, the anode of the second organic light emitting element is spaced apart from an anode of the third organic light emitting element by a second distance, and the first distance is longer than the second distance.

2. The display panel of claim 1, wherein the anode of the third organic light emitting element is spaced apart from the anode of the first organic light emitting element by a third distance, and the third distance is longer than the first distance.

3. The display panel of claim 2, wherein one side of the anode of the second organic light emitting element is parallel with at least one side of the anode of the first organic light emitting element, and another side of the anode of the second organic light emitting element is parallel with at least one side of the anode of the third organic light emitting element.

4. The display panel of claim 1, wherein the anode of the second organic light emitting element has an octagonal shape, and each of the anode of the first organic light emitting element and the anode of the third organic light emitting element has a polygonal shape.

5. The display panel of claim 4, wherein a major axis of the anode of the second organic light emitting element extends in a direction toward the anode of the third organic light emitting element, and a minor axis of the anode of the second organic light emitting element extends in a direction toward the anode of the first organic light emitting element.

6. The display panel of claim 1, wherein an area of the anode of the first organic light emitting element is different from an area of the anode of the third organic light emitting element.

7. The display panel of claim 6, wherein the area of the anode of the first organic light emitting element is smaller than the area of the anode of the third organic light emitting element.

8. The display panel of claim 7, wherein an area of the anode of the second organic light emitting element is smaller than the area of the anode of the first organic light emitting element.

9. The display panel of claim 1, wherein an area of the anode of the first organic light emitting element is equal to an area of the anode of the third organic light emitting element.

10. The display panel of claim 9, wherein an area of the anode of the second organic light emitting element is smaller than the area of the anode of the first organic light emitting element and the area of the anode of the third organic light emitting element.

11. An organic light emitting display device comprising:
a display panel which includes a plurality of first pixels each including a first organic light emitting element which outputs a red color light, a plurality of second pixels each including a second organic light emitting element which outputs a green color light, and a plurality of third pixels each including a third organic light emitting element which outputs a blue color light; and
a display panel driving circuit which drives the display panel,
wherein the display panel has a pixel arrangement structure in which the first organic light emitting elements are arranged in point symmetry with respect to the second organic light emitting element, the third organic light emitting elements are arranged in point symmetry with respect to the second organic light emitting element, an anode of the first organic light emitting element is spaced apart from an anode of the second organic light emitting element by a first distance, the anode of the second organic light emitting element is spaced apart from an anode of the third organic light emitting element by a second distance, and the first distance is longer than the second distance.

12. The display device of claim 11, wherein the anode of the third organic light emitting element is spaced apart from the anode of the first organic light emitting element by a third distance, and the third distance is longer than the first distance.

13. The display device of claim 12, wherein one side of the anode of the second organic light emitting element is parallel with at least one side of the anode of the first organic light emitting element, and another side of the anode of the second organic light emitting element is parallel with at least one side of the anode of the third organic light emitting element.

14. The display device of claim 11, wherein the anode of the second organic light emitting element has an octagonal shape, and each of the anode of the first organic light emitting element and the anode of the third organic light emitting element has a polygonal shape.

15. The display device of claim 14, wherein a major axis of the anode of the second organic light emitting element extends in a direction toward the anode of the third organic light emitting element, and a minor axis of the anode of the second organic light emitting element extends in a direction toward the anode of the first organic light emitting element.

16. The display device of claim 11, wherein an area of the anode of the first organic light emitting element is different from an area of the anode of the third organic light emitting element.

17. The display device of claim 16, wherein the area of the anode of the first organic light emitting element is smaller than the area of the anode of the third organic light emitting element.

18. The display device of claim 17, wherein an area of the anode of the second organic light emitting element is smaller than the area of the anode of the first organic light emitting element.

19. The display device of claim 11, wherein an area of the anode of the first organic light emitting element is equal to an area of the anode of the third organic light emitting element.

20. The display device of claim 19, wherein an area of the anode of the second organic light emitting element is smaller than the area of the anode of the first organic light emitting element and the area of the anode of the third organic light emitting element.
